(19) United States
(12) Patent Application Publication
(10) Pub. No.: US 2009/0057714 A1
(43) Pub. Date: Mar. 5, 2009

(54) THYRISTOR AND METHODS FOR PRODUCING A THYRISTOR

(75) Inventors: Hans-Joachim Schulze, Taufkirchen (DE); Franz-Josef Niedernostheide, Muenster (DE); Uwe Kellner-Werdehausen, Leutenbach (DE); Reiner Barthelmess, Soest (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: Infineon Technologies AG, Neubiberg (DE)

(21) Appl. No.: 12/200,331

(22) Filed: Aug. 28, 2008

(30) Foreign Application Priority Data
Aug. 30, 2007 (DE) 102007041124.5-33

(51) Int. Cl. H01L 21/332; H01L 29/76

(52) U.S. Cl. 257/157; 438/133; 257/E29.226; 257/E21.388

(57) ABSTRACT

A thyristor having a semiconductor body in which a p-doped emitter, an n-doped base, a p-doped base and an n-doped main emitter are arranged successively in a vertical direction starting from a rear face toward a front face. For buffering of the transient heating, a metallization is applied to the front face and/or to the rear face and includes at least one first section which has an area-specific heat capacity of more than 50 J·K⁻¹·m⁻² at each point.

### CROSS-REFERENCE TO RELATED APPLICATIONS

This Utility Patent Application claims priority to German Application No. DE 10 2007 041 124.5-33, filed Aug. 30, 2007, which is herein incorporated by reference.

### BACKGROUND

This disclosure relates to a thyristor including an amplifying gate structure. In thyristors such as these, when the rate of current rise is high, for example when the thyristor is triggered in the switching mode with pulse durations of the thyristor current of 1 μs to 100 μs with a high applied voltage by a light pulse or by an integrated overvoltage protection function, failures can occur in the area of one amplifying gate when the subsequent amplifying gate does not take over the current at the right time.

One measure to avoid such damage is to integrate a lateral resistance within the amplifying gate structure in the semiconductor body of the thyristor, thus preventing an excessive rate of current rise. However, this resistance must not be chosen to be excessively high since, otherwise, an excessively high switch-on voltage occurs, and the trigger delay time also becomes too long. Furthermore, the lateral resistance can be heated during switch on since the voltage dropped across it may be more than 50% of the anode-cathode voltage of the thyristor, and the entire trigger current flows through this lateral resistance. Particularly in the case of high blocking capability thyristors with reverse voltages of up to about 13 kV, this can lead to not inconsiderable heating of the semiconductor body, which in turn influences the electrical characteristics of the lateral resistance and, in the worst case, reduces its electrical resistance. In consequence, the thyristor is no longer effectively protected when high rates of current rise occur during the triggering process. Accordingly, there is a need for improvement.

For these and other reasons, there is a need for the present invention.

### SUMMARY

One embodiment relates to a thyristor which includes a semiconductor body in which in a vertical direction—starting from a rear face toward a front face—a p-doped emitter, an n-doped base, a p-doped base and an n-doped main emitter are arranged successively. The thyristor further includes an amplifying gate structure with at least one n-doped amplifying gate emitter. In order to buffer the transient heating, a metallization is applied to the front face and/or to the rear face of the semiconductor body and includes at least one first section which is in the form of buffer metallization, that is to say it has an area-specific heat capacity of more than 50 J·K⁻¹·m⁻² at room temperature (300 K) at each point. That face of the semiconductor body to which the relevant section of the metallization is applied acts as a reference area for determination of the area-specific heat capacity.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates a plan view of the front face of an embodiment of a thyristor.

FIG. 2 illustrates an enlarged view of the section 11 as illustrated in FIG. 1, with the amplifying gate area of the thyristor.

FIG. 3 illustrates a vertical section through one section of the amplifying gate area of the thyristor illustrated in FIGS. 1 and 2.

FIG. 4a illustrates an enlarged view of a section 12, as can be seen from FIG. 3, including the third amplifying gate and a lateral resistance which is arranged between the second amplifying gate and the third amplifying gate.

FIG. 4b illustrates a modification of the section illustrated in FIG. 4a, in which a barrier layer including three partial layers is arranged between the semiconductor body and the buffer metallization.

FIG. 5 illustrates a modification of the thyristor section 12 illustrated in FIGS. 3 and 4a, in which a section of the metallization of the third amplifying gate extends over a dielectric which is arranged between the metallization of the third amplifying gate and the semiconductor body.

FIG. 6 illustrates a method for production of a thyristor arrangement.

FIG. 7 illustrates an embodiment of a thyristor arrangement.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

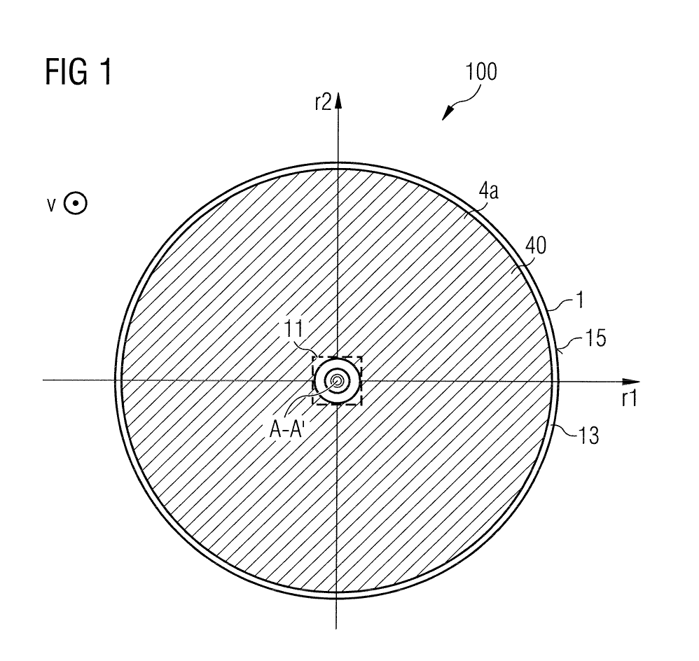

FIG. 1 illustrates a plan view of the cathode of a thyristor 100. The thyristor includes a semiconductor body 1 which is essentially in the form of a flat cylinder extending parallel to a plane which is covered by the lateral directions r1, r2. In this disclosure, the expression “lateral direction” refers not only to the directions r1 and r2 but to any direction whose direction vector runs parallel to this plane. The direction at right angles to the lateral directions r1, r2 is referred to in the following text as the vertical direction v. As can be seen from FIG. 1, the thyristor 100 may optionally be designed to be rotationally symmetrical with respect to an axis A-A′ which runs in the vertical direction v.

The semiconductor body 1 includes a semiconductor basic material, for example silicon or silicon carbide, and includes p-doped and n-doped sections which essentially gather the electrical characteristics of the thyristor 100. A Metallization 4a is applied to the front face 13 of the semiconductor body 1 and, at least in places, has an area-specific heat capacity which is greater than a predetermined area-specific minimum heat capacity, for example 50J·K⁻¹·m⁻² at room temperature (300 K). In general, that face of the semiconductor body 1 to which the relevant metallization is applied acts as a reference area for determination of the area-specific heat capacity. In the case of the front-face metallization 4a, the reference area is the front face 13 of the semiconductor body 1, and in the case of rear-face metallization, which cannot be seen in the present view, it is a rear face opposite the front face of the semiconductor body.

Those areas of the front-face metallization 4a and/or of the rear-face metallization which have an area-specific heat capacity which is greater than the specified area-specific minimum heat capacity are also referred to in the following text as buffer metallization since—in addition to possible other functions—they are used for thermal buffering of transient heat peaks in the semiconductor body 1. If one area of metallization or a metallization section has non-uniform thicknesses and/or non-uniform materials, the only areas which are regarded as buffer metallization are those which have an area-specific heat capacity which is greater than the specified area-specific minimum heat capacity, at each point. A metallization section which has an area-specific heat capacity which is higher than the area-specific minimum heat capacity only in one subarea is not buffer metallization for the purposes of the present application. In contrast, that subarea does represent buffer metallization.

The front-face metallization 4a has a section 40 which is electrically conductively connected to the n-doped main emitter 5 of the thyristor 100. This section 40 extends to close to the side edge 15 of the thyristor 100 and may optionally be in the form of buffer metallization.

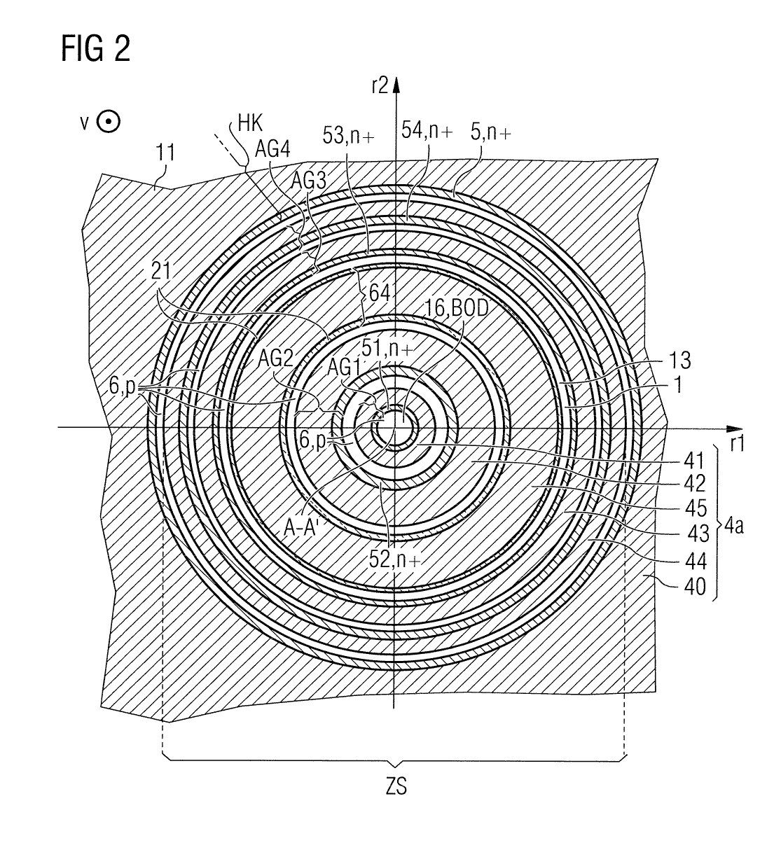

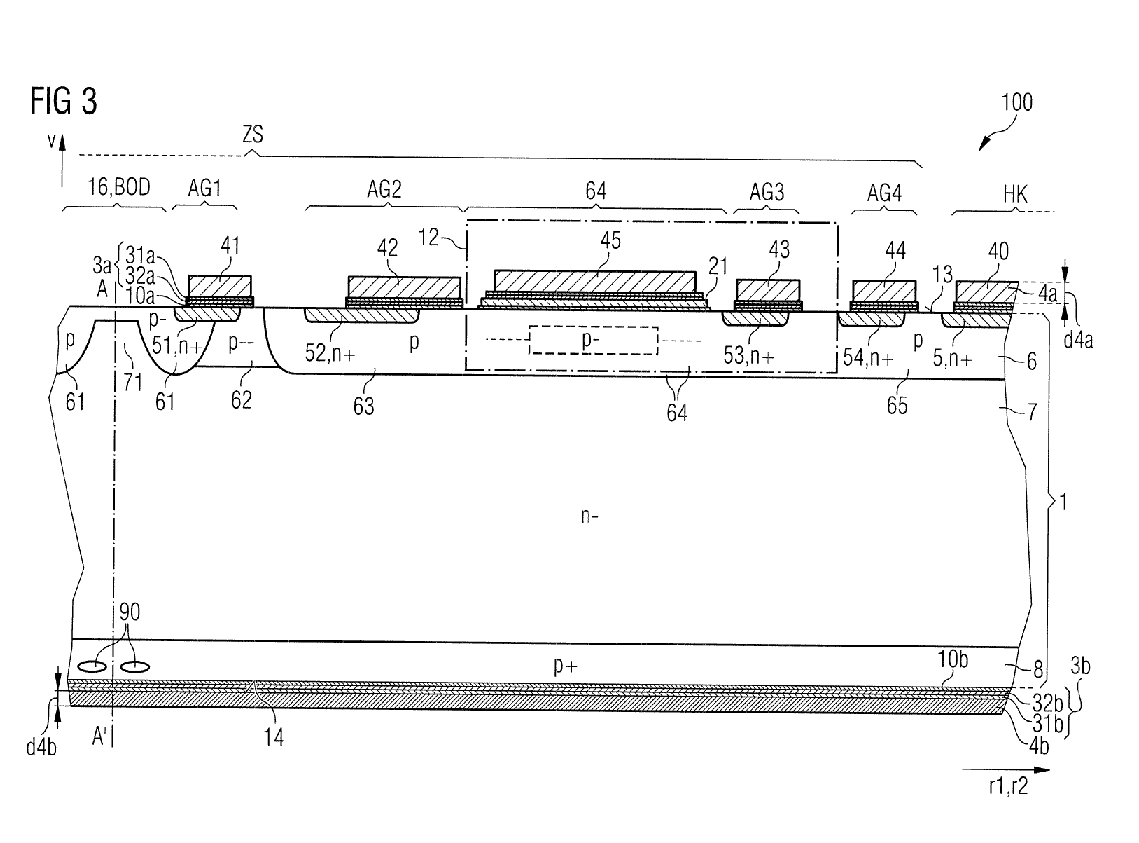

FIG. 2 illustrates a central section 11 of the thyristor 100, enlarged. The central section 11 includes, by way of example, four amplifying gates AG1, AG2, AG3 and AG4 which are arranged successively and at a distance from one another in the lateral direction r1, r2. The amplifying gates AG1, AG2, AG3, AG4 each include a heavily n-doped amplifying gate emitter, 51, 52, 53 or 54, respectively. Each of these amplifying gate emitters 51, 52, 53 or 54, respectively, is electrically conductively connected to a respective section 41, 42, 43 or 44 of the front-face metallization 4a of the thyristor 100, and partially overlaps this respective section 41, 42, 43 or 44 in the lateral direction r1, r2. As illustrated, the amplifying gate emitters 51, 52, 53, 54 and the sections 41, 42, 43, 44 may each have an annular shape. A device 16, which is in the form of a breakover diode (BOD) and will be explained in more detail later with reference to FIG. 3, is arranged within the innermost amplifying gate emitter 51 of the amplifying gate emitters 51-54 of the thyristor 100. Each of the amplifying gate emitters 51-54 projects over the relevant section 41-44, which is electrically conductively connected to it, on its side facing the breakover structure BOD.

A lateral resistance 64 is provided in the semiconductor body 1 between the second amplifying gate AG2 and the third amplifying gate AG3, in which lateral resistance 64 the electrical conductivity of the p-doped base 6 is reduced in comparison to the sections 63 and 64 adjacent to it, and is used to limit the current, as explained initially, through the two inner amplifying gates AG1 and AG2. Instead of or in addition to reduced electrical conductivity of the lateral resistance 64, the thickness of the p-doped base 6 in the lateral resistance 64, measured in the vertical direction v, may be reduced in comparison to the sections 63 and 65 adjacent to the lateral resistance 64.

A second section 45 of the front-face metallization 4a which is electrically isolated from the semiconductor body 1 by a dielectric 21 is arranged above the lateral resistance 64 on the front face 13. Just one, more than one or all of the sections 41 to 45 may optionally be in the form of buffer metallization. For example, only or at least the section 45 may be in the form of buffer metallization for thermal buffering of the lateral resistance 64, and may be arranged at least in places above the lateral resistance 64 on the front face 13.

FIG. 3 illustrates a vertical section through a section of the amplifying gate area ZS of the thyristor 100. This section includes inter alia, the trigger device 16, the amplifying gates AG1, AG2, AG3, AG4, and the lateral resistance 64. The main cathode area HK is arranged adjacent to the amplifying gate area ZS. In the present exemplary embodiment, the main cathode area HK has an annular shape and surrounds the amplifying gate area ZS (see FIGS. 1 and 2).

A p-doped emitter 8, an n-doped base 7, a p-doped base 6 and an n-doped main emitter 5 are arranged successively in the vertical direction v in the semiconductor body 1, starting from a rear face 14 toward a front face 13, with the n-doped main emitter 5 being located only in the main cathode area HK.

By way of example, the trigger device 16 is in the form of a breakover diode BOD which is created by a section 71 of the n-doped base 7 extending further in the direction of the front face 13 of the semiconductor body 1 than in the other areas of the thyristor 100. In the area of the section 71, the pn junction between the n-doped base 7 and a section 61 of the p-doped base 6 has a curvature which leads to a local increase in the electrical field when voltage is applied to the thyristor. This locally decreases the triggering sensitivity of the thyristor 100 such that a reverse current rising in the form of an avalanche breakdown can initiate the triggering of the thyristor 100 in the area of the breakdown structure BOD when a sufficiently high breakover voltage is applied. Instead of or in addition to a trigger device 16 in the form of a breakover diode BOD, the thyristor 100 may also have a gate connection which is electrically conductively connected to the semiconductor body 1 in the area of the section which is arranged within the main emitter 5 and has a p-doped base 6.

The amplifying gate structure with the amplifying gates AG1, AG2, AG3 and AG4 is arranged between the breakover diode BOD and the main cathode area HK. The p-doped base 6 includes the already explained section 61, which is adjacent to the section 71 of the n-doped base 7, as well as further sections 62, 63, 64 and 65. The section 62 is arranged between the sections 61 and 63 and is more lightly doped than the section 61. A section 64 is located between the sections 63 and 65, in which section 64 the electrical conductivity of the p-doped base 6 is reduced in comparison to the electrical conductivity of those sections 63 and 65 of the p-doped base 6 which are adjacent to the section 64. The section 64 is therefore also referred to as a lateral resistance. Alternatively or in addition to a reduced conductivity, a lateral resistance may also be formed by the p-doped base 6 being thinner in the section 64 than in the sections 63 and 65 which are adjacent to the section 64. By way of example, in FIG. 3, the lateral resistance 64 is arranged between the second amplifying gate AG2 and the third amplifying gate AG3. Alternatively or in addition to the lateral resistance 64, an appropriately formed lateral resistance 64 may also be provided between any two adjacent amplifying gates AG1, AG2, AG3, AG4 of the thyristor.

Once triggering of the thyristor has been initiated in the area of the trigger device 16, for example by light incident on the breakover diode BOD, the amplifying gates AG1, AG2, AG3, AG4 and, finally, the main cathode area HK are triggered successively in time, starting in the lateral direction r1, r2. The triggering sensitivity of the amplifying gates AG1, AG2, AG3 and AG4 may decrease, starting from the trigger device 16 toward the main cathode area HK. During the triggering process, the lateral resistance 64 limits the current through the two inner amplifying gates AG1 and AG2.

In order to provide recovery protection, optional n-doped regions 90 are incorporated in the p-doped emitter and act as local transistors which provide additional free charge carriers during the phase in which the thyristor is switched off. The n-doped regions 90 may be in the form of islands, and may be at a distance from one another.

The front-face metallization 4a is applied to the front face 13 of the semiconductor body 1 and includes the section 40, as well as sections 41, 42, 43, 44, one of which is in each case electrically conductively connected to one of the amplifying gate emitters 51, 52, 53 or 54, respectively. A section 45 of the front-face metallization 4a is also arranged on the front face 13 above the lateral resistance 64. Furthermore, rear-face metallization 4b is provided, is applied to the rear face 14 of the semiconductor body 1 and is electrically conductively connected to the p-doped emitter 8. By way of example, the front-face metallization 4a and/or the rear-face metallization 4b, or specific partial layers of these metallizations 4a, 4b, may be produced by using electrolytic deposition such that the front-face metallization 4a and/or the rear-face metallization 4b are/is firmly and non-detachably connected to the semiconductor body 1. In this case, the front-face metallization 4a and the rear-face metallization 4b may both be produced jointly, that is to say in the same deposition process, or independently of one another. Instead of or in addition to electrolytic deposition, the front-face metallization 4a and/or the rear-face metallization 4b, or specific partial layers, for example a barrier layer and/or a contact metallization layer, of these metallizations 4a, 4b may also be sputtered or vapor-deposited onto the semiconductor body 1.

Since the trigger current for the triggering process of the thyristor starts from the trigger device 16 and propagates toward the main cathode area HK, and may have high rates of current rise during the process, the semiconductor body 1 may be transiently heated in the amplifying gate area ZS, in particular in the lateral resistance 64, during the triggering process. In order to limit this heating, the invention provides for the front-face metallization 4a and/or the rear-face metallization 4b to be in the form of buffer metallization, at least in places, that is to say for the relevant metallization 4a or 4b to have, at least in places, an area-specific heat capacity which is greater than an area-specific minimum heat capacity. The area-specific minimum heat capacity may, for example, be 50 J·K⁻¹m⁻² or 65 J·K⁻¹m⁻², at room temperature (300 K).

For example, just one, more or each of the sections 40, 41, 42, 43, 44, 45 of the front-face metallization 4a may be in the form of buffer metallization. For example, the front-face metallization 4a may therefore have a section 41, 42, 43, 44, 45, which represents buffer metallization, at least in the amplifying gate area ZS—for example the section 45 which is arranged above the lateral resistance 64.

Alternatively or in addition to the sections 40-45, the front-face metallization 4a may also include one or more further sections which are in the form of buffer metallization and arranged between adjacent amplifying gate metallizations 41-44 and/or between the metallization 45 of a lateral resistance 64 and amplifying gate metallization 42, 43 adjacent to this metallization 45, and/or between the metallization 40 of the main emitter 5 and the metallization 44 of that amplifying gate emitter 54 which is closest to the main emitter 5. The rear-face metallization 4b may optionally also be in the form of buffer metallization.

In order to achieve the required area-specific heat capacity, buffer metallization 40 to 45, 4b must have an adequate respective thickness d4a or d4b, for example 5 μm to 100 μm or 20 μm to 50 μm. For a predetermined area-specific minimum heat capacity, small thicknesses d4a, d4b of the sections 40 to 45, 4b can be achieved by these sections having a material or being composed of a material in which the product of the density and the specific heat capacity has a high value. One such material, by way of example, is copper with a density of about 8920 kg·m⁻³ and a specific heat capacity of about 385 J·kg⁻¹·K⁻¹ (room temperature values for 300 K).

For adequate thermal buffering of a thyristor area, in particular of the thermally highly loaded areas, the entire buffer metallization in this thyristor area must have a minimum total heat capacity. This can be achieved, inter alia, by specifying a minimum area for the relevant thyristor area over which the buffer metallization must extend in this thyristor area. The normal projection of the buffer metallization and to that surface area to which the buffer metallization is applied is used as a measure of the area of buffer metallization.

By way of example, the buffer metallization which is arranged in the amplifying gate area ZS may extend over a total area of 1/10 to ¾ of the area of the amplifying gate area, for example over 0.1 cm² to 1.2 cm².

One of the buffer metallizations 41, 42, 43, 44 which is electrically conductively connected to one of the amplifying gate emitters 51, 52, 53, 54 may likewise extend over an area of 1/100 to ⅕ of the area of the amplifying gate area, for example over 0.01 cm² to 0.2 cm².

In addition, the total area over which all of the buffer metallizations 41, 42, 43, 44 which are electrically conductively connected to a amplifying gate emitter 51, 52, 53, 54 may extend over 1/10 to ⅕ of the area of the amplifying gate area, for example over 0.15 cm² to 0.3 cm².

Furthermore, the area of buffer metallization 45 which is electrically isolated from the semiconductor body 1 and is arranged in the amplifying gate area ZS may, for example, be ⅓ to ⅔, for example 0.5 cm² to 1 cm², of the area of the amplifying gate area.

Optional barrier layers 3a and 3b, respectively, may also be provided between the metallization layers 4a, 4b and the semiconductor body 1, preventing or at least considerably reducing diffusion of metal from the metallization layers 4a, 4b into the semiconductor body 1. Barrier layers 3a, 3b such as these may be necessary if the material which is used for the metallization layers 4a, 4b can change the electrical characteristics of the thyristor. For example, copper acts as a recombination center or generation center in silicon. A barrier layer therefore suppresses or reduces the diffusion of at least one metal from the metallization layers 4a, 4b into the semiconductor body 1. For this purpose, the barrier layer 3a, 3b may have, for the relevant metal, a diffusion length which, for example—with respect to a temperature of 400° C. to 500° C.—is less than the thickness or less than half the thickness of the barrier layer 3a, 3b.

The front-face barrier layer 3a includes a first partial layer 31a and a second partial layer 32a, and the rear-face barrier layer 3b includes a first partial layer 31b and a second partial layer 32b. The second partial layers 32a, 32b are arranged between the associated first partial layer 31a and 31b, respectively, of the same respective barrier layer 3a or 3b and the semiconductor body 1.

In contrast to this, a barrier layer 3a, 3b such as this may also include only a single partial layer, instead of two partial layers 31a/32a or 31b/32b, respectively, and may have a structure corresponding to that of the first partial barriers 31a, 31b. Furthermore, the barrier layer 3a, 3b may also be composed of more than two partial layers.

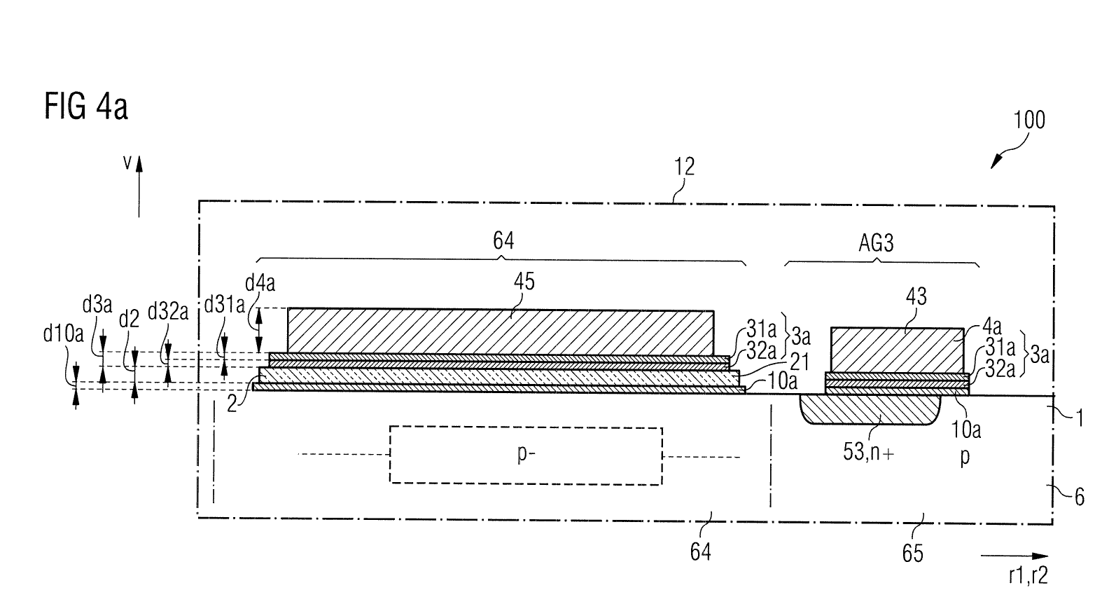

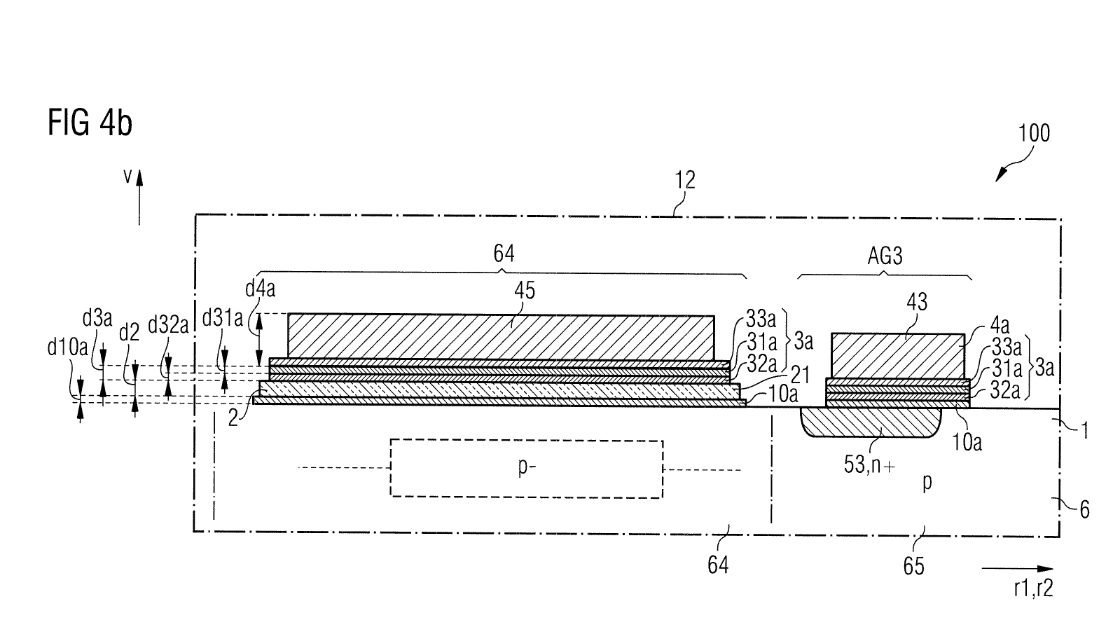

FIG. 4a illustrates, enlarged, a section 12 of the thyristor 100 with the lateral resistance 64 and its metallization 45, and with the third amplifying gate AG3. Referring to this illustration, the structure of a barrier layer will be explained in the following text with reference to the front-face barrier layer 3a. However, the rear-face barrier layer 3b may be formed in the same way as the front-face barrier layer 3a. In this case, the first partial layers 31a, 31b likewise correspond, in the same way as the second partial layers 32a and 32b. In the exemplary embodiment illustrated in FIG. 4a, the front-face barrier layer 3a includes just the two partial layers 31a, 32a.

By way of example, the first partial layer 31a may have a thickness d31a more than 50 nm, of 100 nm to 500 nm, or of 100 nm to 300 nm. By way of example, titanium nitride (TiN), tantalum nitride (TaN) or titanium tungsten (TiW) are suitable as the material for the first partial layer 31a. If titanium tungsten is used, the tungsten component may be, for example, 50% to 100%, or 70% to 90% (Ti_{X}W_{y}, where y=0.5 to 1.0 or where y=0.7 to 0.9).

By way of example, the optional second partial layer 32a may have a thickness d32a of 5 nm to 20 nm, for example about 10 nm, or of at least 50 nm. In addition, the thickness d32a of the second partial layer 32a may be, for example, 100 nm to 500 nm. By way of example, titanium or tantalum, or mixtures, for example alloys composed of or with at least one of these substances, is or are suitable as the material for the second partial layer 32a.

The following table lists examples of possible layer thicknesses of suitable first and second partial layers of suitable barrier layers, in conjunction with suitable materials. The configuration of barrier layers and partial layers thereof is, however, not restricted to the values, materials and number of partial layers indicated.

| First partial layer | | Second partial layer | |
|---|---|---|---|
| Material | Thickness/nm | Material | Thickness/nm |
| TiN | 100-500 | Ti | 100-500 |
| TaN | 100-500 | Ta | 100-500 |
| TiW | >50 | Ti | ~10 |
| TiₓW_{y} (Y = 0.5-1.0) | 100-300 | Ti | ~10 |
| TiₓW_{y} (Y = 0.7-0.9) | 100-300 | Ti | ~10 |

| | | |
|---|---|---|
| TiₓW_{y} (Y = 0.5-1.0) | 100-300 | no second partial layer |
| TiₓW_{y} (Y = 0.7-0.9) | 100-300 | no second partial layer |

As can be seen from FIG. 4b, a barrier layer 3a may have an optional further partial layer 33a, which is arranged between the upper partial layer 31a, the two partial layers 31a and 32a, and buffer metallization 43, 45. In a corresponding manner, the rear-face barrier layer 3b could have an optional further partial layer which is arranged between the partial layer 31b and the rear-face metallization 4b. An optional further partial layer such as this may, for example, consist of tantalum or include tantalum.

In order to electrically isolate that section 45 of the front-face metallization 4a which is arranged above the lateral resistance 64 from the semiconductor body 1, a section 21 of a dielectric layer 2 can be arranged on the semiconductor body 1 between the section 45 and the semiconductor body 1, for example between the front-face barrier layer 3a and the semiconductor body 1. By way of example, silicon dioxide, silicon nitride or polyimide is suitable as the material for the dielectric layer 2. The section 45 of the metallization layer 4a is not electrically connected to the semiconductor body 1 of the thyristor 100 and is therefore also referred to as “floating”.

The thyristor 100 may optionally have a further layer 10a, which is applied directly to the semiconductor body 1. The further layer 10a may be used as a seed layer and/or as a contact layer. A seed layer carries out the function of an adhesion promoter between the semiconductor body 1 and a further coating applied thereto, for example the layer 32a. A suitably chosen contact layer avoids the formation of a pronounced Schottky contact at the junction between the semiconductor body 1 and its metallization, and makes a sufficiently highly electrically conductive contact between the metallization and the semiconductor body 1, since the work function of the electrons from the metallization into the semiconductor body 1 is low.

Instead of a further layer 10a, which acts both as a seed layer and as a contact layer, it is also possible to first of all apply a contact layer directly to the semiconductor body 1. A seed layer can then in turn be applied to the contact layer. A seed layer may for example, be composed of aluminum or silver, or may include an alloy with at least one of these metals. By way of example, a seed layer may be composed of aluminum, titanium, silver or gold, or may include an alloy with at least one of these metals. The thickness of a seed layer and of a contact layer may each, for example, be 0.2 μm to 5 μm.

A further layer 10a with a dual function as a contact layer and seed layer may, for example, be composed of aluminum or silver, or may include an alloy having at least one of these substances, and may have a thickness d10a of 0.2 to 5 μm.

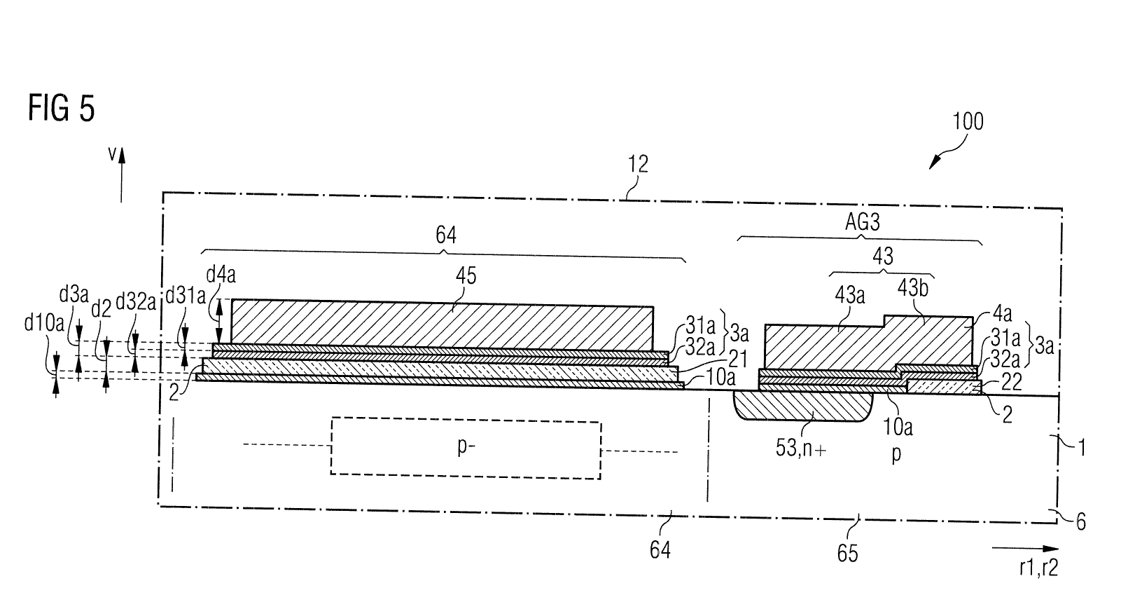

FIG. 5 illustrates a modification of the thyristor section 12 illustrated in FIGS. 3, 4a and 4b. In contrast to the arrangement illustrated in FIGS. 4a and 4b, a section 43b of the metallization 43 of the amplifying gate emitter 53 of the third amplifying gate AG3 extends in the direction of the main emitter 5 over a section 22 of the dielectric layer 2. A section 43a of the buffer metallization 43 corresponds essentially to the buffer metallization 43 illustrated in FIGS. 4a and 4b. The section 22 of the dielectric layer 2 prevents a complete electrical connection between the section 43 and the semiconductor body 1. A structure of metallization 43 of a amplifying gate emitter 53 such as this makes it possible to enlarge the area of the buffer metallization 43 without significantly influencing the electrical characteristics of the amplifying gate AG3. A refinement of buffer metallization 43 of a amplifying gate emitter 53 such as this can additionally or alternatively also be chosen for each of the other metallizations 41, 42, 44 of the respective amplifying gate emitters 51, 52 and 54 of the thyristor 100.

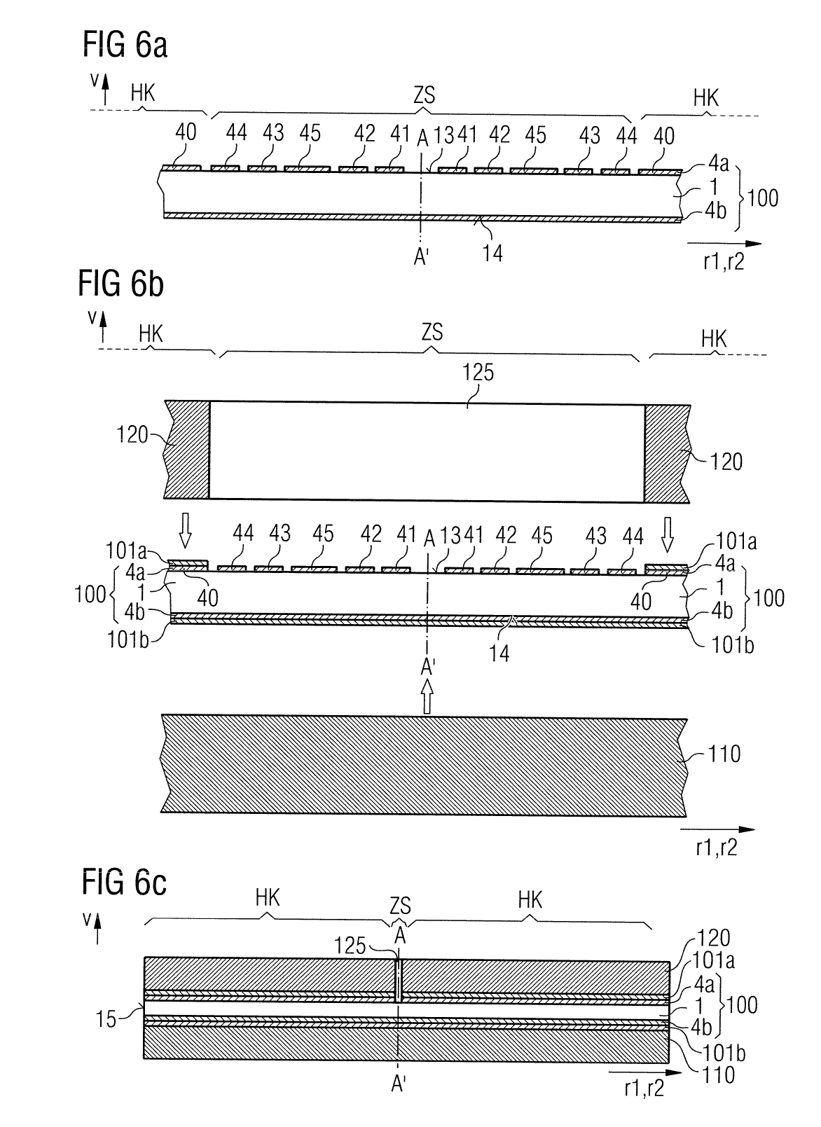

In order to make external contact, the completely processed thyristor 100 may be detachably or non-detachably connected to contact elements. With reference to FIGS. 6a to 6c, the following text explains a method by which the thyristor 100 is electrically conductively and firmly connected to contact elements 110, 120. As can be seen from FIG. 6a, a thyristor 100 is first of all provided for this purpose, and is designed in the same way as the thyristor explained above. For illustrative purposes, FIGS. 6a to 6c do not illustrate barrier layers, dielectric layers, seed layers and doped areas of the semiconductor body 1.

As can be seen from FIG. 6b, a connecting layer 101b is applied to the rear-face metallization layer 4b, and a connecting layer 101a is applied to the front-face metallization 40 of the main emitter. The connecting layers 101a, 101b may, for example, be in the form of diffusion solder layers. A diffusion solder layer such as this may, for example, be composed of a silver-tin alloy or may have a silver-tin alloy. Furthermore, the thickness of a diffusion solder layer 101a, 101b may be, for example, between 1 μm and 50 μm, or between 5 μm and 15 μm. A connection may be made between the contact elements 110, 120 and the thyristor 100 provided with the diffusion solder layers 101a, 101b for example by preheating the contact elements 110, 120 to temperatures which are higher than the melting points of the relevant diffusion solder layers 101a and 1011b, respectively. Once the diffusion solder layers 101a, 101b have solidified, a firm and permanent joint is formed between the contact elements 110, 120 and the thyristor 100. A diffusion solder joint is primarily suitable for small thyristors with a plan area of, for example, less than or equal to 10 cm². FIG. 6c illustrates a vertical section through a thyristor arrangement produced in this way.

As an alternative to a diffusion solder, one or both of the connecting layers 101a, 101b may have silver or may be formed from silver, for example if the joint that is produced has been produced as a low-temperature joint. A low-temperature joint such as this is produced by introducing a powder composed of silver or a powder containing silver between the joint partners, and by pressing them against one another at high pressure and at a raised temperature which, however, is lower than the temperatures which are required to produce diffusion solder joints.

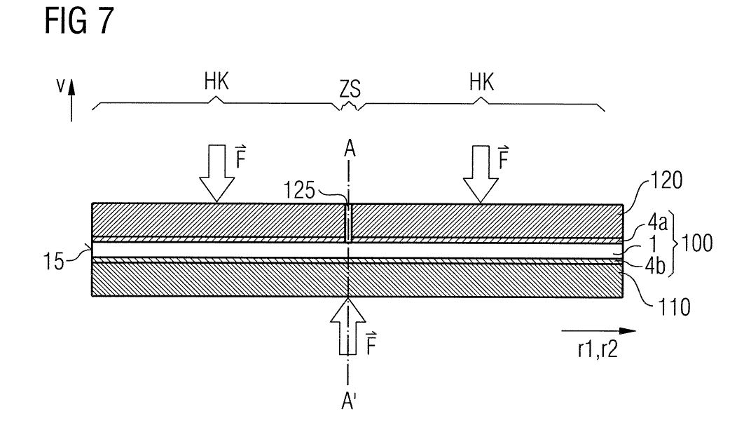

Instead of a fixed and permanent joint such as this between the contact elements 110, 120 and the thyristor 100, one or both of the contact elements 110, 120 may also be detachably connected to one another. In this case, the connecting layers 101a, 101b, as have been explained with reference to FIGS. 6b and 6c, are superfluous. The electrical contact is made just, as illustrated in the thyristor arrangement illustrated in FIG. 7, by the contact elements 110 and/or 120 being pressed against the thyristor 100 by external forces F.

It is also possible for the front-face contact element 120, as explained with reference to FIG. 6, to be firmly and non-detachably connected to the semiconductor body 1, while the rear-face contact element 110 is just pressed against the semiconductor body 1. Conversely, of course, the rear-face contact element 110 can also be firmly and non-detachably connected to the semiconductor body 1, while the front-face contact element 120 is pressed against the semiconductor body 1.

Irrespective of whether it is detachably or non-detachably connected to the semiconductor body 1, a contact element 110, 120 may, for example, be in the form of a circular blank. In the case of a thyristor which can be triggered by light, the front-face contact element 120 may have an opening 125 (see FIGS. 6b, 6c, 7) in order to allow the incidence of light on the breakover diode BOD (see FIGS. 1 to 3). If required, an optical waveguide can be introduced into the opening 125 for this purpose.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A thyristor comprising:
a semiconductor body having a rear face and a front face;
a p-doped emitter, an n-doped base, a p-doped base and an n-doped main emitter arranged successively in a vertical direction from the rear face toward the front face;
an amplifying gate structure including at least one n-doped amplifying gate emitter; and
a metallization which includes at least one first section which has an area-specific heat capacity of more than 50 J·K⁻¹·m⁻² at each point.

2. The thyristor of claim 1, wherein the first section is arranged on the front face between two adjacent amplifying gates or between that amplifying gate which is located closest to the main cathode and the main cathode, and is electrically isolated from the semiconductor body.

3. The thyristor of claim 2, wherein the first section is arranged at least in places above a lateral resistance of the p-doped base, in which lateral resistance the electrical conductivity of the p-doped base is reduced in comparison to sections of the p-doped base which are adjacent to the lateral resistance in the direction of the amplifying gate structure and in the direction of the main emitter.

4. The thyristor of claim 2, wherein the first section is arranged at least in places above a lateral resistance of the p-doped base, in which lateral resistance the thickness of the p-doped base is reduced in comparison to sections of the p-doped base which are adjacent to the lateral resistance in the direction of the amplifying gate structure and in the direction of the main emitter.

5. The thyristor of claim 1, comprising the first section is arranged on the front face and is electrically conductively connected to an n-doped amplifying gate emitter.

6. The thyristor of claim 1, wherein the first section is arranged on the front face and is electrically conductively connected to the n-doped main emitter.

7. The thyristor of claim 1, wherein the thickness of the first section is in the range from about 5 μm to 100 μm.

8. The thyristor of claim 1, wherein the first section is firmly and non-detachably connected to the semiconductor body.

9. The thyristor of claim 1, wherein a barrier layer is arranged between the semiconductor body and the first section and includes a diffusion length for at least one metal of the first section at a temperature of 400° C. to 500° C., which diffusion length is less than the thickness of the barrier layer.

10. The thyristor of claim 1, wherein a dielectric layer is arranged at least in places on the semiconductor body between the first section and the semiconductor body.

11. The thyristor of claim 1, wherein the metallization comprises a section with an area-specific heat capacity of more than 50 J·K⁻¹·m⁻² at each point, which section is applied to the rear face of the semiconductor body.

12. A thyristor arrangement with a thyristor and with at least one contact element, wherein the thyristor comprises
a semiconductor body having a rear face and a front face;
a p-doped emitter, an n-doped base, a p-doped base and an n-doped main emitter arranged successively in a vertical direction from the rear face toward the front face;
an amplifying gate structure including at least one n-doped amplifying gate emitter; and
a metallization which includes at least one first section which has an area-specific heat capacity of more than 50 J·K⁻¹·m⁻² at each point, wherein the metallization is electrically conductively connected to the at least one contact element.

13. The thyristor arrangement of claim 12, wherein the first section is arranged on the front face between two adjacent amplifying gates or between that amplifying gate which is located closest to the main cathode and the main cathode, and is electrically isolated from the semiconductor body.

14. The thyristor arrangement of claim 13, wherein the first section is arranged at least in places above a lateral resistance of the p-doped base, in which lateral resistance the electrical conductivity of the p-doped base is reduced in comparison to sections of the p-doped base which are adjacent to the lateral resistance in the direction of the amplifying gate structure and in the direction of the main emitter.

15. The thyristor arrangement of claim 13, wherein the first section is arranged at least in places above a lateral resistance of the p-doped base, in which lateral resistance the thickness of the p-doped base is reduced in comparison to sections of the p-doped base which are adjacent to the lateral resistance in the direction of the amplifying gate structure and in the direction of the main emitter.

16. The thyristor arrangement of claim 12, wherein the first section is arranged on the front face and is electrically conductively connected to an n-doped amplifying gate emitter.

17. The thyristor arrangement of claim 12, wherein the first section is firmly and non-detachably connected to the semiconductor body.

18. The thyristor arrangement of claim 12, wherein a first contact element of the contact elements is pressed against the metallization, and in which a detachable electrical pressure contact exists between the metallization and the first contact element.

19. A method for producing a thyristor, the method comprising:
providing a semiconductor body having a rear face and a front face;
providing a p-doped emitter, an n-doped base, a p-doped base and an n-doped main emitter arranged successively in a vertical direction from the rear face toward the front face;
providing an amplifying gate structure with at least one n-doped amplifying gate emitter;
applying a metallization to the semiconductor body, which metallization includes at least one first section which has an area-specific heat capacity of more than 50 J·K⁻¹·m⁻² at each point.

20. The method of claim 19, wherein applying the metallization is carried out by electrolytic deposition of metal on the semiconductor body.

21. The method of claim 19, wherein applying the metallization is carried out such that the first section is arranged on the front face between two adjacent amplifying gates or between that amplifying gate which is located closest to the main cathode and the main cathode, and is electrically isolated from the semiconductor body.

22. The method of claim 19, wherein applying the metallization is carried out such that the first section is arranged at least in places above a lateral resistance of the p-doped base, in which the electrical conductivity of the p-doped base is reduced in comparison to sections of the p-doped base which are adjacent to the lateral resistance in the direction of the amplifying gate structure and in the direction of the main emitter.

23. The method of claim 19, wherein applying the metallization is carried out such that the first section is arranged at least in places above a lateral resistance of the p-doped base, in which the thickness of the p-doped base is reduced in comparison to sections of the p-doped base which are adjacent to the lateral resistance in the direction of the amplifying gate structure and in the direction of the main emitter.

24. A method for producing a thyristor arrangement, the method comprising:
providing a semiconductor body having a rear face and a front face;
providing a p-doped emitter, an n-doped base, a p-doped base and an n-doped main emitter arranged successively in a vertical direction from the rear face toward the front face;
providing an amplifying gate structure with at least one n-doped amplifying gate emitter;
applying a metallization to the semiconductor body, which metallization includes at least one first section which has an area-specific heat capacity of more than 50 J·K⁻¹·m⁻² at each point;
providing at least one contact element; and
producing an electrically conductive connection between the metallization and the at least one contact element.

25. The method of claim 24, wherein:
the first section of the thyristor is arranged on the front face between two adjacent amplifying gates or between that amplifying gate which is located closest to the main cathode and the main cathode, and is electrically isolated from the semiconductor body;
the p-doped base includes a lateral resistance, in which the electrical conductivity and/or the thickness of the p-doped base is reduced in comparison to sections of the p-doped base which are adjacent to the lateral resistance in the direction of the amplifying gate structure and in the direction of the main emitter; and
the first section is arranged at least in places above the lateral resistance.
